(19) United States
(12) Patent Application Publication
(10) Pub. No.: US 2025/0327172 A1
(43) Pub. Date: Oct. 23, 2025

(54) COBALT-TITANIUM ALLOY SPUTTERING TARGET ASSEMBLY AND METHOD OF MAKING

(71) Applicant: Honeywell International Inc., Charlotte, NC (US)

(72) Inventors: Xiaodan Wu, Spokane, WA (US); Susan D. Strothers, Mead, WA (US); Rashmi Mohanty, Liberty Lake, WA (US); Alicia Im, Troy, MI (US)

(21) Appl. No.: 19/174,301

(22) Filed: Apr. 9, 2025

Related U.S. Application Data
(60) Provisional application No. 63/636,698, filed on Apr. 19, 2024.

(51) Int. Cl. C23C 14/34; C22C 1/04; C22C 19/07

(52) U.S. Cl. CPC C23C 14/3414; C22C 1/0433; C22C 19/07

(57) ABSTRACT

A method of making a cobalt-titanium sputtering target is provided in which the sputtering target includes 0.5 atomic percent to 24.9 atomic percent titanium. A sputtering target assembly and a method of making a sputtering target assembly are also provided.

### CROSS-REFERENCE TO RELATED PATENT APPLICATIONS

The present application claims the benefit of priority to U.S. Provisional Patent Application No. 63/636,698, filed Apr. 19, 2024, which is incorporated herein by reference in its entirety.

### TECHNICAL FIELD

The present disclosure relates to cobalt-titanium alloy sputtering target assemblies and methods of making such sputtering target assemblies. The cobalt-titanium alloy sputtering target assemblies discussed herein can be used in semiconductor fabrication.

### BACKGROUND

Physical vapor deposition methodologies are used extensively for forming thin films of material over a variety of substrates. One area of importance for such deposition technology is semiconductor fabrication. A diagrammatic view of a portion of an exemplary physical vapor deposition (“PVD”) apparatus 8 is shown in FIG. 1. In one configuration, a sputtering target assembly 10 comprises a backing plate 12 having a target 14 bonded thereto. A substrate 18, such as a semiconductive material wafer, is within the PVD apparatus 8 and provided to be spaced from the target 14. A surface 16 of target 14 is a sputtering surface. As shown, the target 14 is disposed above the substrate 18 and is positioned such that sputtering surface 16 faces substrate 18. In operation, sputtered material 22 is displaced from the sputtering surface 16 of target 14 and used to form a coating (or thin film) 20 over substrate 18.

Cobalt-titanium alloys are next-generation candidates for the barrier layer of an interconnect. The power density used in the sputtering target chamber will likely be high. Thus, a diffusion-bonded target may be necessary. The most common backing plate material is a copper alloy. However, cobalt-titanium alloys and copper alloys have different coefficients of thermal expansion (CTE), which can cause thermal stress at the bonding interface between the cobalt-titanium sputtering target and copper alloy backing plate, leading to either debonding or cracking of the sputtering target.

An improved sputtering target assembly is needed.

### SUMMARY

In Embodiment 1, a method of making a cobalt-titanium sputtering target includes combining cobalt metal powder and titanium metal powder to form a powder mixture containing 0.5 atomic percent (at. %) titanium to 24.9 at. % titanium and the remainder cobalt and impurities, and vacuum hot pressing the powder mixture at about 800° C. to about 1150° C. at a hydraulic pressure of about 2 ksi (13.8 MPa) to about 5 ksi (34.5 MPa) and for a hold time of about 2 hours to about 5 hours to form a cobalt-titanium sputtering target having a density of at least 95%.

In Embodiment 2, the method of Embodiment 1 wherein the titanium powder has a purity of about 3N5 to about 5N.

In Embodiment 3, the method of Embodiment 1, wherein the cobalt powder has a purity of about 3N5 to about 5N.

In Embodiment 4, the method of Embodiment 1, wherein the vacuum hot pressing is at about 1000° C. to about 1150° C.

In Embodiment 5, the method of Embodiment 4 wherein the vacuum hot pressing is at a hydraulic pressure of about 2.5 ksi (17.2 MPa) to about 4 ksi (27.6 MPa).

In Embodiment 6, the method of Embodiment 5 wherein the hold time is about 2 hours to about 4 hours.

In Embodiment 7, the method of Embodiment 1 wherein the density is at least 99%.

In Embodiment 8, the method of Embodiment 1 wherein powder mixture contains 10 atomic percent (at. %) titanium to 20 at. % titanium and the remainder cobalt and impurities.

In Embodiment 9, a sputtering target assembly includes a powder metallurgy high purity cobalt-titanium alloy sputtering target having a density of at least 95%, a copper alloy backing plate diffusion bonded to the sputtering target, and an interlayer positioned between the sputtering target and the backing plate. The interlayer includes an optional first layer directly adjacent to the sputtering target and consisting of copper, a second layer directly adjacent to the first layer if the first layer is present or directly adjacent to the sputtering target if the first layer is not present, wherein the second layer consists of copper, and a third layer directly adjacent to the second layer on a first side and the backing plate on an opposite side, wherein the third layer consists of copper.

In Embodiment 10, the sputtering target assembly of Embodiment 9 wherein powder metallurgy high purity cobalt-titanium alloy sputtering target consists of 0.5 atomic percent (at. %) titanium to 24.9 at. % titanium and the remainder cobalt and impurities.

In Embodiment 11, the sputtering target assembly of Embodiment 9 wherein the powder metallurgy high purity cobalt-titanium alloy sputtering target consists of 10 atomic percent (at. %) titanium to 20 at. % titanium.

In Embodiment 12, the sputtering target assembly of Embodiment 9 wherein the sputtering target has a density of at least 99%.

In Embodiment 13, a method of forming a sputtering target assembly includes diffusion bonding a sputtering target to a second copper layer at a high bond temperature to form an intermediate plated sputtering target, the sputtering target consisting of 0.5 atomic percent (at.) titanium to 24.9 at. % titanium and the remainder cobalt and impurities; positioning a first side of a third copper layer immediately adjacent to a backing plate and a side opposite the first side of the third copper layer immediately adjacent to the second layer to form an assembly; and diffusion bonding the assembly at a low bond temperature to form a sputtering target assembly.

In Embodiment 14, the method of Embodiment 13 wherein the powder metallurgy high purity cobalt-titanium alloy sputtering target consists of 10 atomic percent (at. %) titanium to 20 at. % titanium.

In Embodiment 15, the method of Embodiment 13 wherein the bond strength is at least 10 ksi (68.9 MPa).

In Embodiment 16, the method of Embodiment 13 wherein the sputtering target assembly is suitable for use in a high power sputtering chamber.

In Embodiment 17, the method of Embodiment 13 wherein the powder metallurgy high purity cobalt-titanium alloy sputtering target has an average grain size less than about 100 μm.

In Embodiment 18, the method of claim 13 and further including plating a first copper layer on the powder metallurgy high purity cobalt-titanium alloy sputtering target prior to diffusion bonding the powder metallurgy high purity cobalt-titanium alloy sputtering target to the second copper layer, and wherein diffusion bonding the powder metallurgy high purity cobalt-titanium alloy sputtering target to the second copper layer includes positioning the second copper layer immediately adjacent to the first copper layer.

In Embodiment 19, the method of Embodiment 13 wherein the high bond temperature is from about 600° C. to about 1000° C.

In Embodiment 20, the method of Embodiment 13 wherein the low bond temperature is from about 250° C. to about 500° C.

While multiple embodiments are disclosed, still other embodiments of the present invention will become apparent to those skilled in the art from the following detailed description, which shows and describes illustrative embodiments of the invention. Accordingly, the drawings and detailed description are to be regarded as illustrative in nature and not restrictive.

### BRIEF DESCRIPTION OF THE DRAWINGS

FIG. 1 is a schematic illustration of a sputtering apparatus.

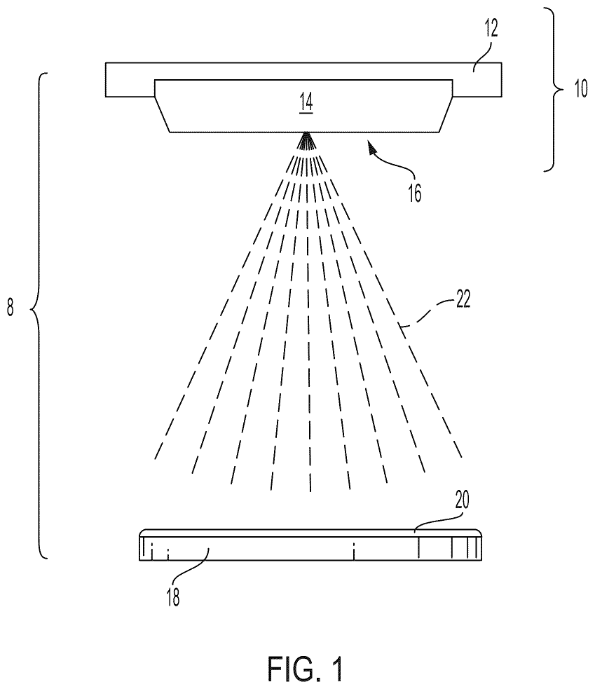

FIG. 2 is a schematic cross-sectional illustration of an exemplary cobalt-titanium sputtering target assembly.

FIG. 3 is a block diagram for making a cobalt-titanium sputtering target assembly.

FIG. 4 is a SEM image of a cobalt-titanium sputtering target.

FIG. 5 is a EBSD map of a cobalt-titanium sputtering target.

FIG. 6 is a histogram of grain size of a cobalt-titanium sputtering target.

FIG. 7 is an X-Ray diffraction pattern of a cobalt-titanium sputtering target.

### DETAILED DESCRIPTION

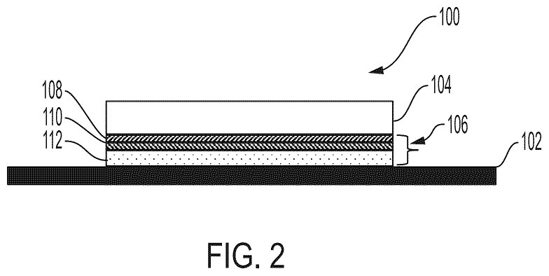

Disclosed herein is an improved cobalt-titanium sputtering target and a method of making the same. FIG. 2 is a schematic cross-sectional view of sputtering target assembly 100 which includes backing plate 102, sputtering target 104 and interlayer 106 which includes optional first layer 108, second layer 110 and third layer 112. Backing plate 102 and sputtering target 104 are joined by a diffusion bond.

Sputtering target 104 is a cobalt-titanium alloy which can include inevitable impurities. For example, sputtering target 104 can consist of cobalt and titanium and inevitable impurities. In some embodiments, the cobalt-titanium alloy can contain cobalt as the primary metal or the base metal and titanium as the alloying metal. In some embodiments, the cobalt-titanium alloy contains from about 0.5 atomic percent (at. %) to about 24.9 at. % or from about 10 at. % to about 20 at. % titanium and the remainder is cobalt. Sputtering target 104 has a purity sufficient for use, for example, to form a barrier layer in semiconductor fabrication. In one example, sputtering target 104 has a purity of at least about 99.95% or 3N5. In some embodiments, sputtering target 104 is free of iron except as may be present as an impurity.

Sputtering target 104 has a sufficient average grain size for interconnect material. For example, sputtering target 104 can have an average grain size less than about 100 micrometers (μm). In some examples, sputtering target 104 can have an average grain size less than about 50 μm. In some examples, sputtering target 104 has a mean grain size less than about 10 μm. In some embodiments, the average grain size can be determined using electron backscatter diffraction (EBSD). In some embodiments, the grain size is measured using EBSD according to ASTM E2627-2013.

Sputtering target 104 has a density sufficient for PVD. In some examples, sputtering target 104 has a density of at least 95%. In other examples, sputtering target 104 has a density of at least 99% or at least 100%. In some embodiments, the density can be measured by Archimedes method.

As described herein, sputtering target 104 can be formed from powder metallurgy. For example, sputtering target 104 can be formed by vacuum hot pressing cobalt in powder form and titanium in powder form.

The cobalt powder can be a high purity powder. For example, the cobalt powder can have a purity of about 3N5 to about 5N. The titanium powder can be a high purity powder. For example, the titanium powder can have a purity of about 3N5 to about 5N.

Backing plate 102 can be formed from a copper alloy, such as a copper zinc alloy, a copper chromium alloy or a copper chromium nickel silicon alloy. For example, backing plate 102 may be formed from C46400 (a CuZn alloy), C18200 (a Cu-1% Cr alloy) or C18000 (a CuCrNiSi alloy). In some embodiments, backing plate 102 is a CuZn alloy. It was found that an insufficient bond was formed between backing plate 102 and sputtering target 104 when a low bonding temperature (e.g. less than 250° C.) was used. Because of the difference in the coefficient of thermal expansion (CTE) of sputtering target 104 and backing plate 102, a higher bonding temperature may cause thermal stress between the two pieces which would lead to debonding or cracking of sputtering target 104. For example, the CTE of a standard CuZn backing plate is about 20 μm/m. K and the CTE of Co-15 at. % Ti is about 12.4 μm/m·K, using the rule of mixtures.

Interlayer 106 improves the bonding of sputtering target 104 to backing plate 102. Interlayer 106 includes first layer 108 (optional), second layer 110 and third layer 112. First layer 108 is a copper layer and when present, is directly or immediately adjacent to sputtering target 104. In some embodiments, first layer 108 consists of or consists essentially of copper. First layer 108 is a thin layer. For example, first layer 108 can have a thickness from about 1 to about 10 microns.

Second layer 110 is directly adjacent to first layer 108 on a first side when first layer 108 is present and directly adjacent to sputtering target 104 on a first side when first layer 108 is not present. Second layer 110 is directly adjacent to third layer 112 on the side opposite the first side. Second layer 110 is formed from a copper foil, such as an oxygen-free copper, such as Cu-OFE (oxygen fee electronic grade). In some embodiments, second layer 110 is formed of copper that is oxygen-free up to 99.99%. Second layer 110 is a thin layer. For example, second layer 110 can have a thickness from about 0.010 to about 0.100 inches (about 0.254 millimeter (mm) to about 2.54 mm). In some examples, second layer 110 can be formed from a copper foil that is about 0.025 inches in thickness.

Third layer 112 is directly adjacent to second layer 110 on a first side and backing plate 102 on an opposite side. Third layer 112 can be also formed from copper. For example, third layer 112 can be formed from an oxygen-free copper, such as Cu-OFE. In some embodiments, third layer 112 is formed of copper that is oxygen-free up to 99.99%. In some embodiments, third layer 112 has a thickness from about 0.1 inches to about 0.3 inches (about 2.5 mm to about 7.62 mm).

Sputtering target 104 and backing plate 102 are diffusion bonded to one another. In some embodiments, sputtering target 104 and backing plate 102 are bonded by hot isostatic pressing (HIP) or vacuum hot press. In some embodiments, the bond strength is at least 10 kilopounds per square inch (ksi) (68.9 megapascal).

Thermal stress at the bonding interface between sputtering target 104 and backing plate 102 occur as the sputtering target assembly cools following diffusion bonding. Thermal stress at the bonding interface can also occur during the duty cycle of the sputtering. The thermal stress can cause either debonding or cracking of sputtering target 104. Sputtering target 104, interlayer 106 and a two-step diffusion bonding process as described herein produce a sputtering target assembly with suitable properties to be used in a high power PVD chamber (i.e., 10 kilowatts (kW) or greater) for semiconductor manufacturing, such as the barrier layer of an interconnect. For example, sputtering target 104 may be able to withstand sputtering at 10 kW or greater without warping.

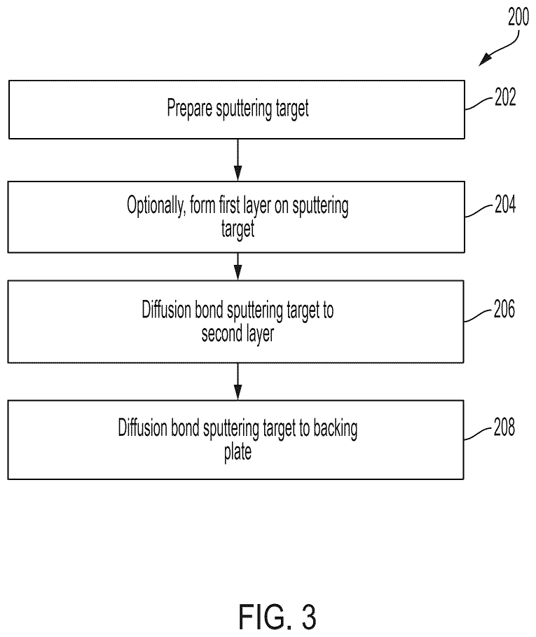

FIG. 3 is a diagram of process 200 for making sputtering target assembly 100. In step 202, sputtering target 104 is created using powder metallurgy. For example, cobalt powder and titanium powder can be formed into a sputtering target using vacuum hot press. For example, high purity cobalt powder and high purity titanium powder can be mixed to form the desired cobalt/titanium mixture and loaded into the die of a vacuum hot press machine. In some embodiments, cobalt powder is mixed with about 0.5 at. % to about 24.9 at. % titanium powder. In some embodiments, cobalt powder is mixed with about 5 at. % to about 20 at. %, or 10 at. % to about 20 at. % titanium powder. In some embodiments the cobalt powder can have a purity of at least 4N (99.99%) and/or a particle size of 200 mesh and the titanium powder can have a purity of at least 4N and/or a particle size of 325 mesh.

The mixed power is vacuum hot pressed to form a cobalt-titanium alloy sputtering target. In some embodiments, the vacuum hot press is at a temperature of about 800° C. to about 1150° C., a hydraulic pressure of about 2 ksi (13.8 megapascals (MPa)) to about 5 ksi (34.5 MPa) and uses a hold time of about 2 hours to about 5 hours. In some embodiments, the vacuum hot press is at 1000° C. to about 1150° C., 2.5 ksi (17.2 MPa) to 4 ksi (27.6 MPa) and a hold time of 2 hours to 4 hours. In some embodiments, the vacuum hot press is at 1000° C. to about 1150° C., 3 ksi (20.7 MPa) to 4 ksi (27.6 MPa) and a hold time of 2 hours to 4 hours. The sputtering target has a density of at least 95%. In some embodiments, the sputtering target has a density of at least 99% or at least 100%.

In step 204, optionally, the first layer is formed directly on the back surface of the sputtering target. As described herein, the first layer is a thin layer of copper. In some embodiments, the first layer can be formed by electroplating, PVD process or ion plating. In some embodiments, the first layer can be about 1 to about 10 microns thick. The first layer acts as an adhesion layer and joins the sputtering target to the second layer.

In step 206, the second layer is formed on the sputtering target. In embodiments in which the first layer is present, the second layer can be formed by diffusion bonding the second layer to the first layer on the sputtering target. In embodiments in which the first layer is not present, the second layer can be formed by diffusion bonding the second layer directly to the back surface of the sputtering target. In some embodiments, the second layer is an oxygen-free copper foil. The second layer can be joined to the first layer (if present) or to the back surface of the sputtering target by a high temperature diffusion bond. For example, the assembly can be hot pressed at about 600° C. to about 1000° C. The second layer provides a bonding surface to the third layer. The copper of the second layer and the copper of the third layer provide a copper-to-copper bond for the assembly.

In Step 208, the sputtering target with the first layer (optional) and the second layer is joined to a backing plate by diffusion bonding. In Step 208, a third layer is placed immediately adjacent to the second layer on the sputtering target and a backing plate is placed immediately adjacent to the third layer. This assembly is bonded by hot isostatic pressing (HIP) at a low temperature to form sputtering target assembly 100 of FIG. 2. For example, the assembly can be bonded at a temperature from about 250° C. to about 500° C.

The low bonding temperature of step 208 minimizes the thermal stress between the sputtering target and the backing plate, which prevents target cracking. The usage of the second layer provides a CTE gradient between the sputtering target and backing plate.

### Example 1

A cobalt-titanium alloy samples containing 15 at. % titanium (Co-15Ti alloy) was prepared by vacuum hot pressing a mixture of cobalt power and titanium powder at 1200° C. and 3.5 ksi (24.1 MPa) for 2 hours.

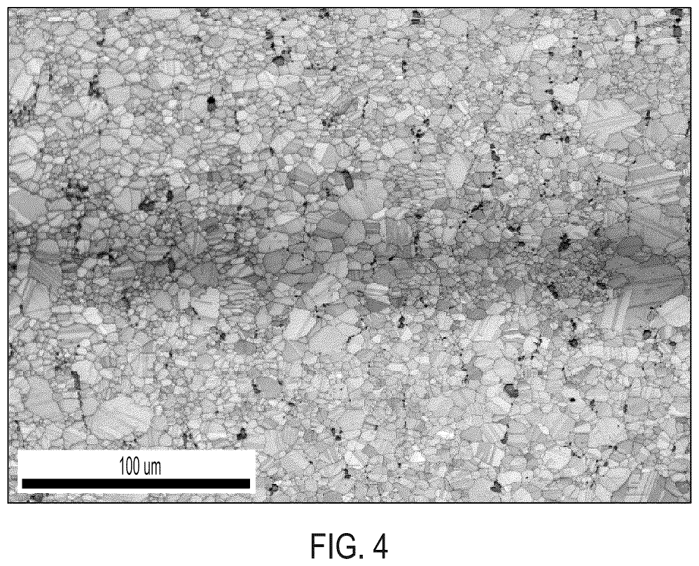

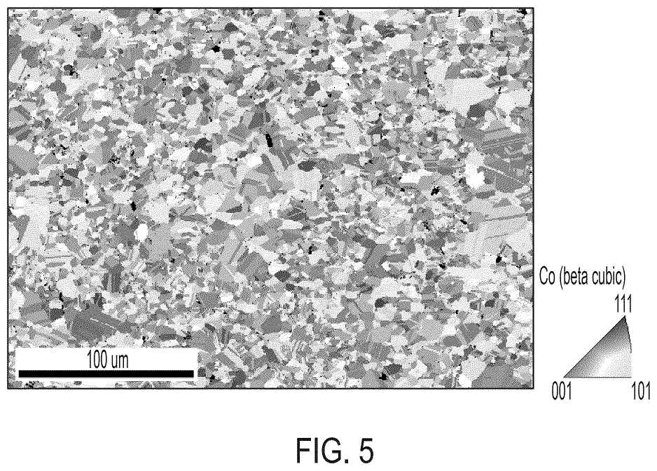

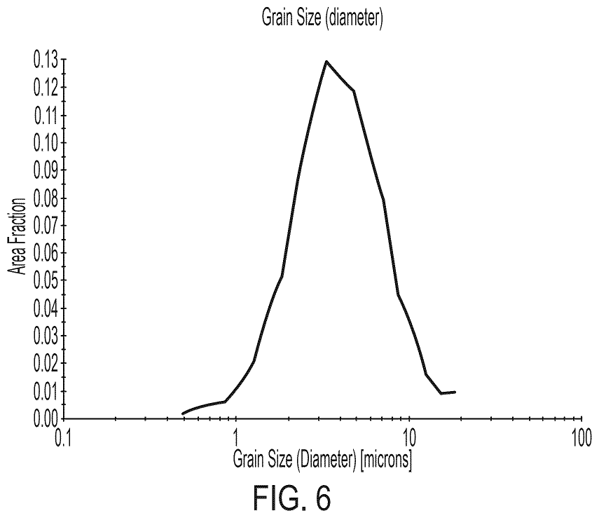

The density of the sputtering target can be measured by the Archimedes method. The transverse rupture strength can be determined using ASTM B528-16. FIG. 4 is an scanning electron microscope (SEM) image of the cobalt-titanium alloy. The image shows that the alloy has a small grain size. The grain size can be measured by EBSD. FIG. 5 is an electron backscatter diffraction (EBSD) map of the alloy. The mean value of the grain size was 4.6 μm. FIG. 6 is a histogram of the grain size (diameter, in microns).

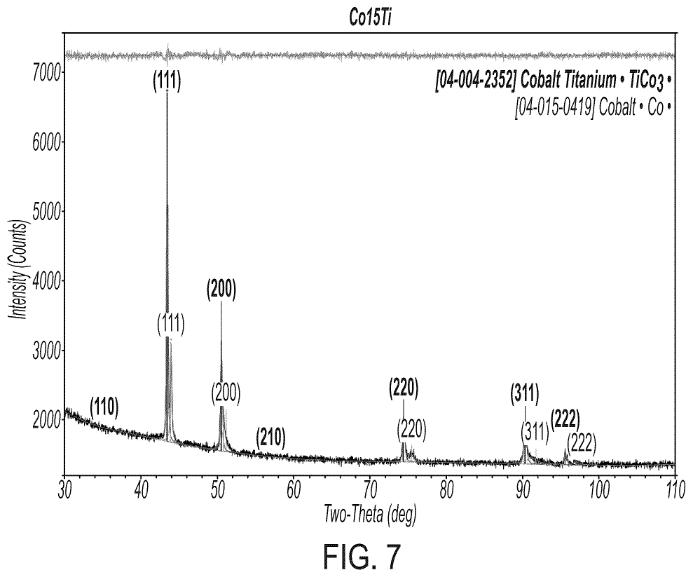

The X-Ray diffraction (XRD) pattern of the alloy is provided in FIG. 7. Based on XRD analysis, it is believed that the alloy has two phases: TiCo₃ and α-Co. The phase concentrations are provided in Table 1.

TABLE 1

| | Concentration |
|---|---|
| Phases Identified | (±5 wt %) |
| TiCo₃ - Cobalt Titanium Cubic | 67.2% |
| α-Co - Cobalt Cubic | 32.8% |

### Prophetic Example 1

The cobalt-titanium alloy of Example 1 can be diffusion bonded to copper-zinc alloy C46400. The bond can be analyzed by C-Scan and the bond strength can be determined by RAM tensile test method as described in Zatorski, Z. (2007) Evaluation of Steel Clad Plate Weldability Using Ram Tensile Test Method. Engineering Transactions, 55(3), 229-238.

Various modifications and additions can be made to the exemplary embodiments discussed without departing from the scope of the present invention. For example, while the embodiments described above refer to particular features, the scope of this invention also includes embodiments having different combinations of features and embodiments that do not include all of the above-described features.

What is claimed is:

1. A method of making a cobalt-titanium sputtering target, the method comprising:
combining cobalt powder and titanium powder to form a powder mixture containing 0.5 atomic percent (at. %) titanium to 24.9 at. % titanium and the remainder cobalt and impurities; and
vacuum hot pressing the powder mixture at about 800° C. to about 1150° C. at a hydraulic pressure of about 2 kilopounds per square inch (ksi) (13.8 MPa) to about 5 ksi (34.5 MPa) and for a hold time of about 2 hours to about 5 hours to form a cobalt-titanium sputtering target having a density of at least 95%.

2. The method of claim 1, wherein the titanium powder has a purity of about 3N5 to about 5N.

3. The method of claim 1, wherein the cobalt powder has a purity of about 3N5 to about 5N.

4. The method of claim 1, wherein the vacuum hot pressing is at about 1000° C. to about 1150° C.

5. The method of claim 4 wherein the vacuum hot pressing is at a hydraulic pressure of about 2.5 ksi (17.2 MPa) to about 4 ksi (27.6 MPa).

6. The method of claim 5 wherein the hold time is about 2 hours to about 4 hours.

7. The method of claim 1 wherein the density is at least 99%.

8. The method of claim 1 wherein powder mixture contains 10 atomic percent (at. %) titanium to 20 at. % titanium and the remainder cobalt and impurities.

9. A sputtering target assembly comprising:
a powder metallurgy cobalt-titanium alloy sputtering target having a density of at least 95%;
a copper alloy backing plate diffusion bonded to the sputtering target; and
an interlayer positioned between the sputtering target and the backing plate, the interlayer comprising:
an optional first layer directly adjacent to the sputtering target and consisting of copper;
a second layer directly adjacent to the first layer if the first layer is present or directly adjacent to the sputtering target if the first layer is not present, wherein the second layer consists of copper; and
a third layer directly adjacent to the second layer on a first side and the backing plate on an opposite side, wherein the third layer consists of copper.

10. The sputtering target assembly of claim 9 wherein the powder metallurgy cobalt-titanium alloy sputtering target consists of 0.5 atomic percent (at. %) titanium to 24.9 at. % titanium and the remainder cobalt and impurities.

11. The sputtering target assembly of claim 9 wherein the powder metallurgy cobalt-titanium alloy sputtering target consists of 10 atomic percent (at. %) titanium to 20 at. % titanium.

12. The sputtering target assembly of claim 9 wherein the sputtering target has a density of at least 99%.

13. A method of forming a sputtering target assembly, the method comprising:
diffusion bonding a powder metallurgy cobalt-titanium alloy sputtering target to a second copper layer at a high bond temperature to form an intermediate plated sputtering target, the powder metallurgy cobalt-titanium alloy sputtering target consisting of 0.5 atomic percent (at. %) titanium to 24.9 at. % titanium and the remainder cobalt and impurities;
positioning a first side of a third copper layer immediately adjacent to a backing plate and a side opposite the first side of the third copper layer immediately adjacent to the second layer to form an assembly; and
diffusion bonding the assembly at a low bond temperature to form a sputtering target assembly.

14. The method of claim 13 wherein the powder metallurgy cobalt-titanium alloy sputtering target consists of 10 atomic percent (at. %) titanium to 20 at. % titanium.

15. The method of claim 13 wherein the bond strength is at least 10 ksi (68.9 MPa).

16. The method of claim 13 wherein the sputtering target assembly is suitable for use in a high power sputtering chamber.

17. The method of claim 13 wherein the powder metallurgy cobalt-titanium alloy sputtering target has an average grain size less than about 100 μm.

18. The method of claim 13 and further comprising:
plating a first copper layer on the powder metallurgy cobalt-titanium alloy sputtering target prior to diffusion bonding the powder metallurgy cobalt-titanium alloy sputtering target to the second copper layer; and wherein diffusion bonding the powder metallurgy cobalt-titanium alloy sputtering target to the second copper layer includes positioning the second copper layer immediately adjacent to the first copper layer.

19. The method of claim 13 wherein the high bond temperature is from about 600° C. to about 1000° C.

20. The method of claim 13 wherein the low bond temperature is from about 250° C. to about 500° C.
